(19) United States
(12) Patent Application Publication
(10) Pub. No.: US 2024/0234199 A9
(43) Pub. Date: Jul. 11, 2024

(54) WAFER PLACEMENT TABLE

(71) Applicant: NGK INSULATORS, LTD., Nagoya-City (JP)

(72) Inventors: Tatsuya KUNO, Nagoya-City (JP); Seiya INOUE, Handa-City (JP)

(73) Assignee: NGK INSULATORS, LTD., Nagoya-City (JP)

(21) Appl. No.: 18/299,130

(22) Filed: Apr. 12, 2023

Related U.S. Application Data
(63) Continuation of application No. PCT/JP2022/039689, filed on Oct. 25, 2022.

(51) Int. Cl. H01L 21/687; H01J 37/32

(52) U.S. Cl. CPC H01L 21/68785; H01J 37/3244; H01J 37/32724; H01L 21/68757; H01J 2237/002

(57) ABSTRACT

A wafer placement table includes: a ceramic plate including a wafer placement portion having a reference surface on which a number of small protrusions are provided; a cooling plate including a refrigerant flow path; a joining layer with which the ceramic plate and the cooling plate are joined; a recessed groove provided in the reference surface and having a bottom surface positioned lower than the reference surface; a plug arrangement hole passing through the ceramic plate and being open to the bottom surface of the recessed groove; a porous plug disposed in the plug arrangement hole, the porous plug having a top surface positioned at the same height as the bottom surface of the recessed groove and allowing gas to flow; and a gas supply path through which gas is supplied to the porous plug.

### BACKGROUND OF THE INVENTION

### 1. Field of the Invention

The present invention relates to a wafer placement table.

### 2. Description of the Related Art

There have been known wafer placement tables including a ceramic plate incorporating an electrode, a cooling plate including a refrigerant flow path, and a joining layer for joining the ceramic plate and the cooling plate to one another. For example, PTL 1 discloses a wafer placement table including a ceramic plate having a through hole passing therethrough, and a porous plug is joined to the through hole by sintering. Gas is supplied to the porous plug through a gas supply path provided in a cooling plate. When such a wafer placement table is manufactured, the through hole of the ceramic plate is charged with a ceramic mixture in paste form serving as a precursor to the porous plug, and the ceramic mixture is sintered into the porous plug. When the upper end of the porous plug protrudes from the upper surface of the ceramic plate after sintering, such a protruding portion of the porous plug is ground to make the upper end of the porous plug and the upper surface of the ceramic plate flush with one another.

### CITATION LIST

### Patent Literature

PTL 1: Japanese Unexamined Patent Application Publication No. 2019-29384

### SUMMARY OF THE INVENTION

However, when the protruding portion of the porous plug is ground with a surface plate to make the upper end of the porous plug and the upper surface of the ceramic plate flush with one another, particles may fall off the porous plug and may damage the upper surface of the ceramic plate. In addition, although a space where gas is trapped is not provided on the lower surface side of a wafer in PTL 1, when such a space is provided, a number of small protrusions are required to be formed on the upper surface of the ceramic plate by, for example, blasting. In such a process, when the upper end of the porous plug and the upper surface of the ceramic plate are flush with one another, there has arisen a problem that fine dust enters the porous plug. There has also arisen a problem that a portion of the wafer at a position where the wafer faces the porous plug is likely to have a low temperature.

The present invention has been made to solve such problems, and main objects thereof are to prevent a ceramic plate and a porous plug from having a defect during manufacture and to prevent the thermal uniformity of a wafer from being impaired when in use.
[1] A wafer placement table of the present invention includes: a ceramic plate including a wafer placement portion having a reference surface on which a number of small protrusions that support a wafer are provided, the ceramic plate incorporating an electrode; a cooling plate including a refrigerant flow path; a joining layer with which the ceramic plate and the cooling plate are joined to one another; a recessed groove provided in the reference surface and having a bottom surface positioned lower than the reference surface; a plug arrangement hole passing through the ceramic plate in a thickness direction and being open to the bottom surface of the recessed groove; a porous plug disposed in the plug arrangement hole, the porous plug having a top surface positioned at the same height as the bottom surface of the recessed groove, the porous plug having an outer peripheral surface joined to an inner peripheral surface of the plug arrangement hole, the porous plug allowing gas to flow; and a gas supply path through which gas is supplied to the porous plug.

In the wafer placement table, in a manufacturing process, polishing is sometimes performed on a surface of the ceramic plate (a surface at a position higher than the reference surface of the ceramic plate) having the plug arrangement hole to which the porous plug is joined, the porous plug having the top surface positioned at the same height as the bottom surface of the recessed groove. In such a case, because being at a position lower than the reference surface, the top surface of the porous plug is not polished. In addition, in the subsequent manufacturing process, a number of small protrusions are sometimes formed on the surface of the ceramic plate. In such a case, fine dust can be prevented from entering the porous plug when, after portions of the ceramic plate at positions where the small protrusions are to be formed are masked, and the top surface of the porous plug in the recessed groove is also masked, an un-masked region is ground off. On the other hand, when the wafer placement table is in use, gas is supplied to the porous plug through the gas supply path. In such a case, the pressure of the gas at a position on the wafer where the wafer faces the porous plug is high, and the temperature at such a position is thereby likely to be lower than the temperatures at other positions of the wafer. However, here, the top surface of the porous plug is positioned lower than the reference surface. Thus, compared with when the top surface of the porous plug is positioned at the same height as the reference surface, heat is suppressed from being conducted from the region in the wafer where the wafer faces the porous plug to the ceramic plate. Thus, the temperature in the region can be prevented from being extremely low.

Note that, in the present description, the condition of being the “same” include, in addition to a case of being completely the same, a case of being substantially the same (for example, when within a tolerance range).
[2] In the above-described wafer placement table (the wafer placement table according to the above [1]), the outer peripheral surface of the porous plug may be joined to the inner peripheral surface of the plug arrangement hole by sintering.
[3] In the above-described wafer placement table (the wafer placement table according to the above [2]), the durable temperature of the joining layer may be lower than the sintering temperature of the ceramic plate. When such a wafer placement table is manufactured, the ceramic plate and the cooling plate are required to be joined to one another after the porous plug is joined to the plug arrangement hole of the ceramic plate by sintering. This is because the sintering temperature exceeds the durable temperature of the joining layer when the ceramic plate, whose plug arrangement hole is remained empty, and the cooling plate are joined to one another, and the porous plug is then joined to the plug arrangement hole by sintering.
[4] In the above-described wafer placement table (the wafer placement table according to any one of the above [1] to [3]), the distance from the bottom surface of the recessed groove to the reference surface may be 0.005 mm or more and 0.5 mm or less. When the distance is 0.5 mm or less, electric discharge can be prevented from being caused in the recessed groove even when the wafer is treated with plasma during use of the wafer placement table. In addition, when the distance is 0.005 mm or more, the effect of preventing the ceramic plate and the porous plug from having a defect during manufacture can be obtained.
[5] In the above-described wafer placement table (the wafer placement table according to any one of the above [1] to [4]), the top surface of the porous plug may be covered with a protection cap having a number of pores, and the top surface of the protection cap may be at a position lower than the top surfaces of the small protrusions. With this configuration, the longevity of the porous plug can be increased, and the protection cap can be prevented from lifting the wafer.
[6] In the above-described wafer placement table (the wafer placement table according to any one of the above [1] to [5]), the gas supply path may be a path through which gas is supplied from the lower surface of the cooling plate to the porous plug through a joining-layer through hole provided, in the joining layer, at a position where the joining layer faces the porous plug, and the joining-layer through hole may have a size small enough not to allow the porous plug to pass. With this configuration, the joining layer supports the porous plug from below, and the porous plug can be prevented from falling out of the plug arrangement hole during manufacture or use of the wafer placement table.

### BRIEF DESCRIPTION OF THE DRAWINGS

FIG. 1 is a vertical cross-sectional view of a wafer placement table 10.

FIG. 2 is a plan view of a ceramic plate 20.

FIG. 3 is an enlarged view of a part of FIG. 1.

FIGS. 4A to 4F illustrate manufacturing processes of the ceramic plate 20.

FIGS. 5A to 5C illustrate manufacturing processes of the wafer placement table 10.

FIG. 6 is an enlarged view of a part of another example.

FIG. 7 is an enlarged view of a part of another example.

### DETAILED DESCRIPTION OF THE INVENTION

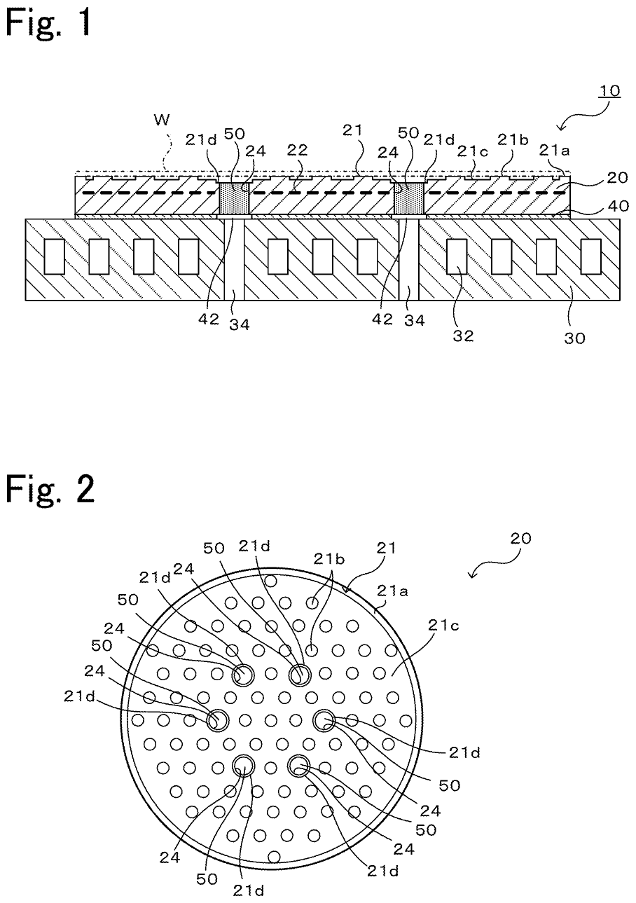

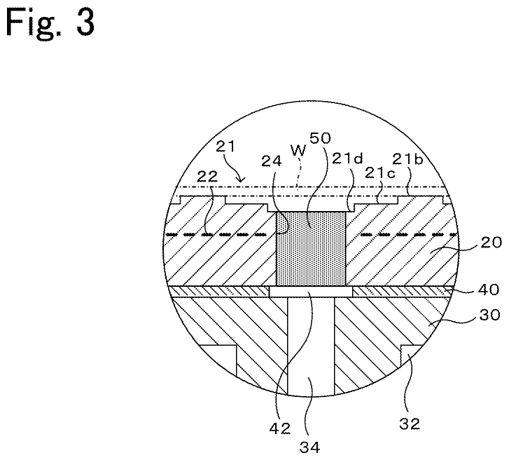

A preferred embodiment of the present invention will be described below with reference to the drawings. FIG. 1 is a vertical cross-sectional view of a wafer placement table 10 (a cross-sectional view taken along a plane including the central axis of the wafer placement table 10), FIG. 2 is a plan view of a ceramic plate 20, and FIG. 3 is an enlarged view of a part of FIG. 1.

The wafer placement table 10 is used for performing, for example, CVD and etching on a wafer W by using plasma and includes the ceramic plate 20, a cooling plate 30, a metal joining layer 40, and porous plugs 50.

The ceramic plate 20 is a disk (for example, 300 mm in diameter, 5 mm in thickness) made of a ceramic such as an alumina sintered body or an aluminum nitride sintered body. A wafer placement portion 21 is provided in the upper surface of the ceramic plate 20. The ceramic plate 20 incorporates an electrode 22. In the wafer placement portion 21, a seal band 21a is formed along the outer edge, and plural small circular protrusions 21b are formed in a region surrounded by the seal band 21a. The seal band 21a and the small circular protrusions 21b have the same height, that is, for example, from several μm to several tens of μm. The electrode 22 is a planar mesh electrode serving as an electrostatic electrode, and a direct current can be applied thereto. When a direct current is applied to the electrode 22, the wafer W is attracted to and fixed to the wafer placement portion 21 (specifically, the upper surface of the seal band 21a and the upper surfaces of the small circular protrusions 21b) by electrostatic attraction force, and the wafer W attracted to and fixed to the wafer placement portion 21 is released when the application of the direct current is cancelled. Note that a portion, of the wafer placement portion 21, on which no seal band 21a or no small circular protrusions 21b are provided is referred to as a reference surface 21c. The reference surface 21c is a horizontal surface.

The reference surface 21c has recessed grooves 21d each having a circular shape in plan view. The bottom surface of each of the recessed grooves 21d is positioned lower than the reference surface 21c. The recessed grooves 21d are provided in plural spots of the ceramic plate 20 (for example, as FIG. 2 illustrates, the plural spots provided in the peripheral direction at regular intervals). The height from the bottom surface of the recessed groove 21d to the reference surface 21c is preferably 0.005 mm or more and 0.5 mm or less, more preferably 0.005 mm or more and 0.2 mm or less, and the height is particularly preferably 0.005 mm or more and 0.1 mm or less in an apparatus that applies high voltage.

Plug arrangement holes 24 are hollow cylindrical holes passing through the ceramic plate 20 in the up-down direction (the thickness direction) and being open to the bottom surfaces of the respective recessed grooves 21d. As with the recessed grooves 21d, the plug arrangement holes 24 are also provided in plural spots of the ceramic plate 20 (for example, as FIG. 2 illustrates, the plural spots provided in the peripheral direction at regular intervals). The porous plugs 50, which will be described later, are arranged in the respective plug arrangement holes 24. The cooling plate 30 is a disk (a disk whose diameter is larger than or equal to the diameter of the ceramic plate 20) having good thermal conductivity. Inside the cooling plate 30, a refrigerant flow path 32 through which refrigerant circulates and gas holes 34 through which gas is supplied to the porous plugs 50 are formed. The refrigerant flow path 32 is formed across an entire surface of the cooling plate 30 in plan view, from the inlet to the outlet of the refrigerant flow path 32, in a one-stroke pattern. The gas holes 34 are hollow cylindrical holes and provided at positions where the cooling plate 30 faces the plug arrangement holes 24. Examples of the material for the cooling plate 30 include metal materials and composite materials of metals and ceramics. Examples of the metal materials include Al, Ti, and Mo and alloys thereof. Examples of the composite materials of metals and ceramics include a metal matrix composite material (Metal matrix composite (MMC)) and a ceramic matrix composite material (Ceramic matrix composite (CMC)). Specific examples of such composite materials include a material containing Si, SiC, and Ti and a material produced by a SiC porous body being impregnated with Al and/or Si. The material containing Si, SiC, and Ti is referred to as SiSiCTi, the material produced by a SiC porous body being impregnated with Al is referred to as AlSiC, and the material produced by a SiC porous body being impregnated with Si is referred to as SiSiC. When the ceramic plate 20 is an alumina plate, a material used for the cooling plate 30 is preferably an MMC (such as AlSiC or SiSiCTi) having a coefficient of thermal expansion close to the coefficient of thermal expansion of alumina.

With the metal joining layer 40, the lower surface of the ceramic plate 20 and the upper surface of the cooling plate 30 are joined to one another. The metal joining layer 40 is formed, for example, through TCB (Thermal compression bonding). TCB is a known method of pressure-joining two members in a state where the two members to be joined, with a metal joining material interposed therebetween, are heated to a temperature lower than or equal to the solidus temperature of the metal joining material. The metal joining layer 40 has joining-layer through holes 42 formed at positions where the metal joining layer 40 faces the gas holes 34 and passing through the metal joining layer 40 in the up-down direction. In the present embodiment, the diameter of each of the joining-layer through holes 42 is smaller than the diameter of each of the porous plugs 50. Thus, the joining-layer through hole 42 has a size small enough not to allow the porous plug 50 to pass.

The porous plug 50 is a columnar plug that allows gas to flow and is disposed in the plug arrangement hole 24. The top surface of the porous plug 50 is at the same height as the bottom surface of the recessed groove 21d. The outer peripheral surface of the porous plug 50 is joined to the inner peripheral surface of the plug arrangement hole 24 by sintering. The lower surface of the porous plug 50 is at the same height as the lower surface of the ceramic plate 20. In the present embodiment, the porous plug 50 is a porous bulk body obtained by ceramic powder being sintered. As for the ceramic, for example, alumina or aluminum nitride can be used. The porosity of the porous plug 50 is preferably 30% or more, and the average pore diameter is preferably 20 μm or more. The porous plug 50 can be prepared according to, for example, the method described in PTL 1.

In the present embodiment, the gas hole 34 of the cooling plate 30 links to an external gas supply device (not illustrated). The gas supplied from the gas supply device into the gas hole 34 is trapped in a space on the lower surface side of the wafer W placed on the wafer placement portion 21, through the gas supply path of the wafer placement table 10 (the gas hole 34, the joining-layer through hole 42, and the porous plug 50). The space on the lower surface side of the wafer W is enclosed with the wafer W, the seal band 21a, the small circular protrusions 21b, the reference surface 21c, the bottom surfaces of the recessed grooves 21d, and the top surfaces of the porous plugs 50.

Next, an example of use of the wafer placement table 10 configured in the above-described way will be described. First, the wafer W is placed on the wafer placement portion 21 with the wafer placement table 10 being mounted in a chamber, which is not illustrated. The pressure inside the chamber is then reduced by a vacuum pump and adjusted so that a predetermined degree of vacuum is achieved, the electrode 22 of the ceramic plate 20 is applied with a direct current to generate electrostatic attraction force, and the wafer W is attracted to and fixed to the wafer placement portion 21 (specifically, the upper surface of the seal band 21a and the upper surfaces of the small circular protrusions 21b). Next, the inside of the chamber is changed to a reactive gas atmosphere at a predetermined pressure (for example, several tens to several hundreds of Pa), and, in this state, plasma is generated by a high frequency voltage being applied across an upper electrode, which is not illustrated, provided at a ceiling portion inside the chamber and the cooling plate 30 of the wafer placement table 10. A surface of the wafer W is treated with the generated plasma. Refrigerant is caused to circulate through the refrigerant flow path 32 of the cooling plate 30. Gas is introduced into the gas holes 34 from the gas supply device, which is not illustrated. As for the gas, a thermal conductive gas (such as helium) is used. The gas passes through the gas holes 34, the joining-layer through holes 42, and the porous plugs 50 and is supplied to and trapped in the space on the lower surface side of the wafer W. Such backside gas facilitates efficient thermal conduction between the wafer W and the ceramic plate 20.

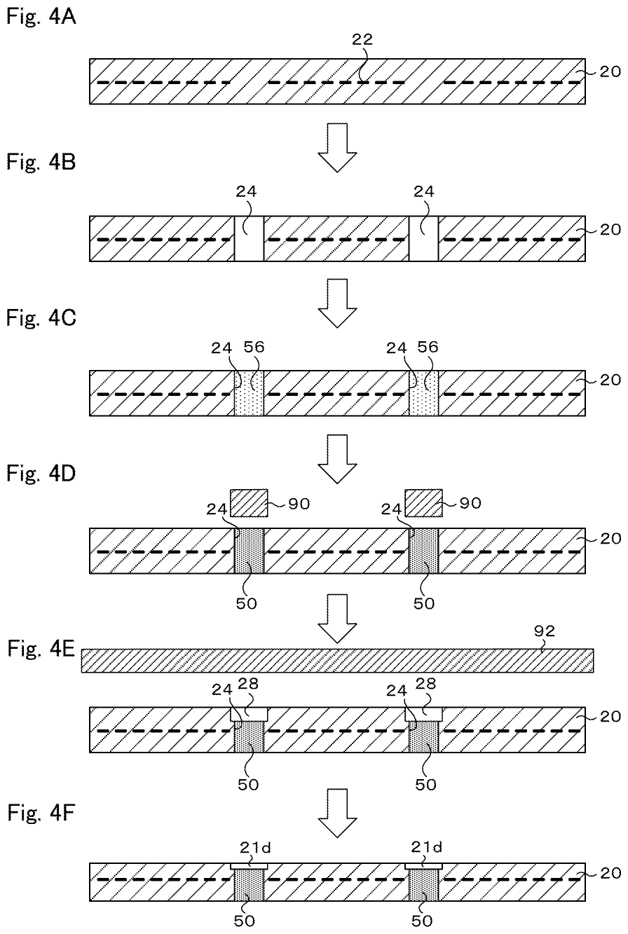

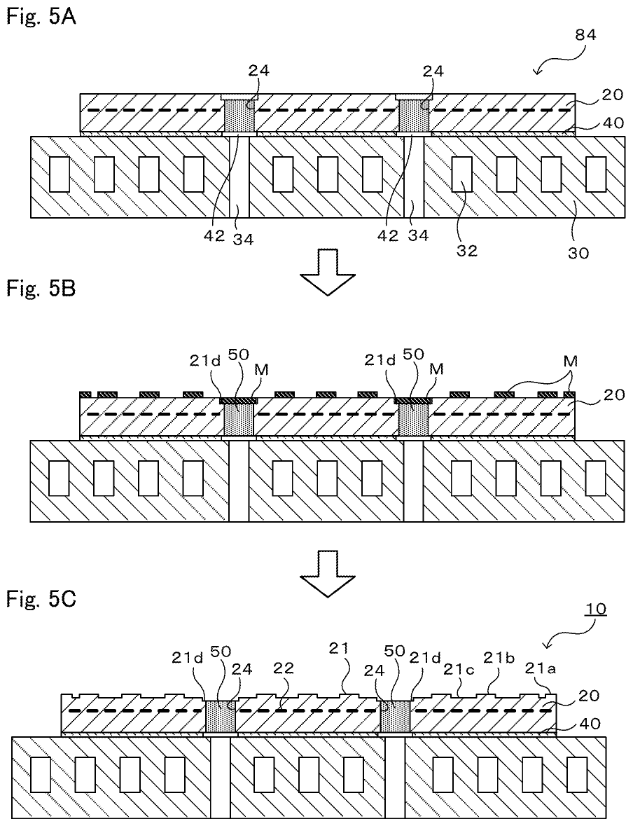

Next, an example of manufacture of the wafer placement table 10 will be described based on FIGS. 4A to 4F and FIGS. 5A to 5C. FIGS. 4A to 4F illustrate manufacturing processes of the ceramic plate 20, and FIGS. 5A to 5C illustrate manufacturing processes of the wafer placement table 10.

First, a disk-shaped ceramic molded body incorporating the electrode 22 is prepared and then fired into the ceramic plate 20 that is a ceramic sintered body (FIG. 4A). The ceramic molded body can be prepared by, for example, raw powder that is constituted by ceramic powder mixed with a material, such as a sintering aid, being charged into a mold and pressure-molded.

Subsequently, the plug arrangement holes 24 are formed in the ceramic plate 20 (FIG. 4B), and a ceramic mixture 56 in paste form serving as a precursor to each of the porous plugs 50 is charged into the plug arrangement holes 24 (FIG. 4C). The ceramic mixture 56 is constituted by a mixture of materials such as ceramic particles, a sintering aid, and burn-off particles. As for the burn-off particles, for example, there are preferably used organic particles that have an average particle size larger than the average particle size of the ceramic particles and burn and disappear when burned at a temperature at which the ceramic particles are sintered.

Subsequently, the ceramic plate 20, each of whose plug arrangement holes 24 has been charged with the ceramic mixture 56, is heated to a temperature at which the ceramic particles of the ceramic mixture 56 can be sintered. Accordingly, the burn-off particles in the ceramic mixture 56 burn off, and the ceramic particles are sintered with each other. In addition thereto, the ceramic particles and the particles of the inner peripheral surface of the plug arrangement hole 24 are sintered. Thus, the porous plugs 50 are formed in the respective plug arrangement holes 24 (FIG. 4D). Each of the porous plugs 50 is a ceramic sintered body having pores. In addition, the outer peripheral surface of the porous plug 50 and the inner peripheral surface of the plug arrangement hole 24 are joined to one another by sintering.

Subsequently, the porous plug 50 and the vicinity thereof are ground with a columnar grinding stone 90 (FIG. 4D), which has a diameter larger than the diameter of the porous plug 50, to form a recessed groove 28 having a circular shape in plan view (FIG. 4E). Subsequently, with a surface plate 92 (FIG. 4E), the upper surface of the ceramic plate 20 is polished (FIG. 4F). Such polishing is continued until the recessed groove 28 has a predetermined depth (the depth of the recessed groove 21d). Through the polishing, the recessed groove 28 is formed into the recessed groove 21d. At this time, because the surface plate 92 is not in contact with the top surface of the porous plug 50, no particles fall out of the top surface of the porous plug 50, and the upper surface of the ceramic plate 20 is not damaged.

Subsequently, the upper surface of the pre-prepared cooling plate 30 (the cooling plate 30 including the refrigerant flow path 32 and having the plural gas holes 34) and the lower surface of the ceramic plate 20 are joined to one another by TCB, and a joined body 84 is obtained (FIG. 5A). TCB is performed as follows, for example. First, a metal joining material is held between the lower surface of the ceramic plate 20 and the upper surface of the cooling plate 30 to form a layered body. At this time, such layering is performed so that the plug arrangement hole 24 of the ceramic plate 20, a round hole formed in the metal joining material in advance, and the corresponding gas hole 34 of the cooling plate 30 are coaxially arranged. The layered body is then pressure-joined at a temperature lower than or equal to the solidus temperature of the metal joining material (for example, being higher or equal to a temperature obtained by deducting 20° C. from the solidus temperature and lower than or equal to the solidus temperature), and, after that, the temperature of the layered body is decreased to a room temperature. Accordingly, the metal joining material is formed into the metal joining layer 40, the round hole of the metal joining material then serves as the joining-layer through hole 42, and there is obtained the joined body 84 formed by the ceramic plate 20 and the cooling plate 30 being joined to one another with the metal joining layer 40. As for the metal joining material here, an Al—Mg joining material or an Al—Si—Mg joining material can be used. For example, when TCB is performed by using the Al—Si—Mg joining material, the layered body is applied with pressure in a state of being heated under vacuum atmosphere. The metal joining material having a thickness of about 100 μm is preferably used.

Subsequently, in the flat upper surface of the ceramic plate 20, a region where the seal band 21a is to be formed and regions where the small circular protrusions 21b are to be formed are covered with masks M, and the bottom surfaces of the recessed grooves 21d (including the top surfaces of the porous plugs 50) are also covered with masks M (FIG. 5B). In this state, an exposed region, in the ceramic plate 20, not being covered with any masks M is subjected to blasting, and the height of the exposed region is reduced. At this time, because the top surface of each of the porous plugs 50 is covered with the mask M, no fine dust is generated from the porous plug 50 due to blasting. Subsequently, the masks are removed. Then, the ceramic plate 20 having the seal band 21a, the small circular protrusions 21b, and the reference surface 21c formed in the upper surface thereof is obtained (FIG. 5C). In the above-described way, the wafer placement table 10 is obtained.

In the wafer placement table 10 detailed above, in a manufacturing process, polishing is performed on a surface of the ceramic plate 20 (a surface at a position at least higher than the reference surface of the ceramic plate) having the plug arrangement holes 24 to which the respective porous plugs 50 are joined, the porous plugs 50 having the top surfaces positioned at the same height as the bottom surfaces of the recessed grooves 28. In such a case, because being at positions lower than the surface of the ceramic plate 20, the top surfaces of the porous plugs 50 are not polished (FIG. 4E and FIG. 4F). In addition, in the subsequent manufacturing process, a number of the small circular protrusions 21b are formed at the surface of the ceramic plate 20. In such a case, fine dust can be prevented from entering the porous plugs 50 because, after portions of the ceramic plate 20 at positions where the small circular protrusions 21b are to be formed are masked, and the top surfaces of the porous plugs 50 in the recessed grooves 21d are also masked, an un-masked region is ground off (FIG. 5B and FIG. 5C).

On the other hand, when the wafer placement table 10 is in use, gas is supplied to each of the porous plugs 50 through the gas supply path (for example, the gas holes 34). In such a case, the pressure of the gas at a position on the wafer W where the wafer W faces the porous plug 50 is high, and the temperature at such a position is thereby likely to be lower than the temperatures at other positions of the wafer W. However, here, the top surface of the porous plug 50 is positioned lower than the reference surface 21c. Thus, compared with when the top surface of the porous plug 50 is positioned at the same height as the reference surface 21c, heat is suppressed from being conducted from the region of the wafer W where the wafer W faces the porous plug 50 to the ceramic plate 20 (because the thermal conductivity of gas is lower than the thermal conductivity of the ceramic plate 20). Thus, the temperature in the region can be prevented from being extremely low.

In addition, the durable temperature of the metal joining layer 40 is lower than the sintering temperature of the ceramic plate 20. Thus, when the wafer placement table 10 is manufactured, the ceramic plate 20 and the cooling plate 30 are required to be joined to one another after the porous plug 50 is joined to the plug arrangement hole 24 of the ceramic plate 20 by sintering. This is because the sintering temperature exceeds the durable temperature of the metal joining layer 40 when the ceramic plate 20, whose plug arrangement hole 24 is remained empty, and the cooling plate 30 are joined to one another, and the porous plug 50 is then joined to the plug arrangement hole 24 by sintering. Thus, the porous plug 50 cannot be mounted in the ceramic plate 20 in the final process of manufacturing the wafer placement table 10. For example, the porous plugs 50 cannot be joined to the respective plug arrangement holes 24 by sintering at the final stage after the wafer placement table 10 with no porous plugs 50 in the plug arrangement holes 24 is prepared.

Moreover, the distance from the bottom surface of each of the recessed grooves 21d to the reference surface 21c is preferably 0.005 mm or more and 0.5 mm or less. If the distance is excessively long, electrons generated with the ionization of gas (for example, helium gas) in the recessed grooves 21d caused when the wafer W is treated with plasma may accelerate and collide with another helium to cause an arc discharge; however, such electric discharge can be prevented from being caused when the distance is 0.5 mm or less. In addition, when the distance is 0.005 mm or more, the effect of preventing the ceramic plate and the porous plug from having a defect during manufacture can be obtained.

The present invention is not limited to the above-described embodiment, and can be carried out by various modes as long as they belong to the technical scope of the invention.

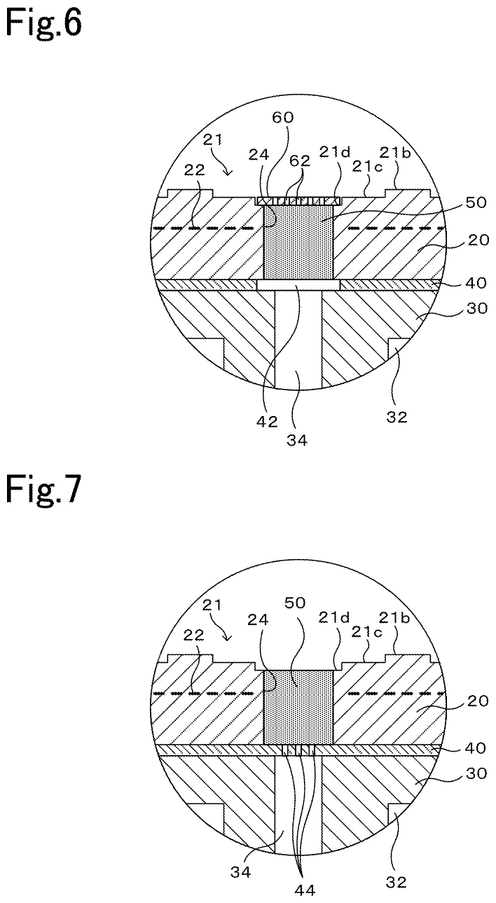

In the above-described embodiment, as FIG. 6 illustrates, the top surface of the porous plug 50 may be covered with a protection cap 60 having a number of pores 62 and having electrical insulation properties. The top surface of the protection cap 60 is at a position lower than the top surface of each of the small circular protrusions 21b (for example, at the same height as the reference surface 21c). With this configuration, the longevity of the porous plug 50 can be increased, and the protection cap 60 can be prevented from lifting the wafer W. Note that, in FIG. 6, the same constituents as those in the above-described embodiment are denoted by the same reference signs.

In the above-described embodiment, as FIG. 7 illustrates, gas may be supplied from the gas hole 34 of the cooling plate 30 to the porous plug 50 through plural small joining-layer-through-holes 44 provided, in the metal joining layer 40, at positions where the metal joining layer 40 faces the porous plug 50. In this case, the metal joining layer 40 also supports the porous plug 50 from below. With this configuration, it is possible to more reliably prevent the porous plug 50 from falling out of the plug arrangement hole 24 during manufacture or use of the wafer placement table 10. Note that, in FIG. 7, the same constituents as those in the above-described embodiment are denoted by the same reference signs.

In the above-described embodiment, after the plug arrangement hole 24 of the ceramic plate 20 is charged with the ceramic mixture 56 in paste form, the ceramic plate 20 is heated to a temperature at which the ceramic particles of the ceramic mixture 56 can be sintered, and the porous plug 50 is thus formed inside the plug arrangement hole 24. However, the formation process of the porous plug 50 is not particularly limited thereto. For example, the porous plug 50 that has been separately prepared may be inserted in the plug arrangement hole 24 of the ceramic plate 20, and a treatment may then be performed at a temperature at which the particles of the outer peripheral surface of the porous plug 50 and the particles of the inner peripheral surface of the plug arrangement hole 24 are sintered. At this time, sintering may be performed after a ceramic mixture in paste form is interposed between the outer peripheral surface of the porous plug 50 and the inner peripheral surface of the plug arrangement hole 24. Alternatively, the porous plug 50 may be formed by ceramic thermal spray films or laser-sintered films being layered on top of another in the empty plug arrangement hole 24 of the ceramic plate 20.

Although, in the above-described embodiment, the gas holes 34 of the cooling plate 30 are provided for the plural porous plugs 50 on a one-to-one basis, the configuration is not particularly limited thereto. For example, instead of providing the gas holes 34, a gas common path having an annular or arc shape in plan view may be formed at the interface between the cooling plate 30 and the metal joining layer 40, a single gas introduction path connected to the gas common path from the lower surface of the cooling plate 30 may be provided, and gas distribution paths through which gas is distributed from the gas common path to the respective porous plugs 50 may be provided.

Although, in the above-described embodiment, an electrostatic electrode is described as an example of the electrode 22 incorporated in the ceramic plate 20, the electrode 22 is not particularly limited thereto. For example, instead of or in addition to the electrode 22, a heater electrode (resistance heating element) or an RF electrode may be incorporated in the ceramic plate 20.

Although, in the above-described embodiment, the ceramic plate 20 and the cooling plate 30 are joined to one another with the metal joining layer 40, a resin adhesion layer may be used instead of the metal joining layer 40. The durable temperature of the resin adhesion layer is lower than the sintering temperature of the ceramic plate 20.

Although, in the above-described embodiment, the small circular protrusion 21b is described as an example of a small protrusion, the small protrusion is not particularly limited thereto. For example, the small protrusion may have a polygonal shape in plan view.

International Application No. PCT/JP2022/039689, filed on Oct. 25, 2022, is incorporated herein by reference in its entirety.

What is claimed is:

1. A wafer placement table comprising:
a ceramic plate including a wafer placement portion having a reference surface on which a number of small protrusions that support a wafer are provided, the ceramic plate incorporating an electrode;
a cooling plate including a refrigerant flow path;
a joining layer with which the ceramic plate and the cooling plate are joined to one another;
a recessed groove provided in the reference surface and having a bottom surface positioned lower than the reference surface;
a plug arrangement hole passing through the ceramic plate in a thickness direction and being open to the bottom surface of the recessed groove;
a porous plug disposed in the plug arrangement hole, the porous plug having a top surface positioned at the same height as the bottom surface of the recessed groove, the porous plug having an outer peripheral surface joined to an inner peripheral surface of the plug arrangement hole, the porous plug allowing gas to flow; and
a gas supply path through which gas is supplied to the porous plug.

2. The wafer placement table according to claim 1,
wherein the outer peripheral surface of the porous plug is joined to the inner peripheral surface of the plug arrangement hole by sintering.

3. The wafer placement table according to claim 2,
wherein a durable temperature of the joining layer is lower than a sintering temperature of the ceramic plate.

4. The wafer placement table according to claim 1,
wherein a distance from the bottom surface of the recessed groove to the reference surface is 0.005 mm or more and 0.5 mm or less.

5. The wafer placement table according to claim 1,
wherein the top surface of the porous plug is covered with a protection cap having a number of pores, and a top surface of the protection cap is at a position lower than top surfaces of the small protrusions.

6. The wafer placement table according to claim 1,
wherein the gas supply path is a path extending from a lower surface of the cooling plate to a lower surface of the porous plug through a joining-layer through hole provided, in the joining layer, at a position where the joining layer faces the porous plug, and
the joining-layer through hole has a size small enough not to allow the porous plug to pass.
